(19) United States
(12) Patent Application Publication
(10) Pub. No.: US 2026/0147269 A1
(43) Pub. Date: May 28, 2026

(54) METHOD FOR GENERATING OPTICAL PROXIMITY CORRECTION PATTERN

(71) Applicant: United Microelectronics Corp., Hsinchu (TW)

(72) Inventors: Hsin-I Hsiao, Taichung City (TW); Pin Han Huang, Tainan City (TW); Ming-Hsien Kuo, Tainan City (TW)

(73) Assignee: United Microelectronics Corp., Hsinchu (TW)

(21) Appl. No.: 19/008,575

(22) Filed: Jan. 2, 2025

(30) Foreign Application Priority Data
Nov. 27, 2024 (TW) 113145718

(51) Int. Cl. G03F 1/36; G03F 7/00

(52) U.S. Cl. CPC G03F 1/36; G03F 7/70441

(57) ABSTRACT

A method for generating an OPC pattern is provided. A layout pattern including a first unit pattern in an edge region and second unit patterns in a central region. A first OPC sub-pattern corresponding to the first unit pattern and the second unit patterns in an edge portion of the central region adjacent to the edge region and a second OPC sub-pattern corresponding to the second unit pattern are built. A mark covering the edge region and the edge portion is formed. The edge region is identified, and a first OPC pattern is obtained according to the first OPC sub-pattern. The central region except the edge portion is identified according to the mark, and a second OPC pattern is obtained according to the second OPC sub-pattern. The first OPC pattern and the second OPC pattern are combined to obtain an OPC pattern of the layout pattern.

### CROSS-REFERENCE TO RELATED APPLICATION

This application claims the priority benefit of Taiwan application serial no. 113145718, filed on Nov. 27, 2024. The entirety of the above-mentioned patent application is hereby incorporated by reference herein and made a part of this specification.

### BACKGROUND

### Technical Field

The present invention relates to a method for generating an optical proximity correction (OPC) pattern.

### Description of Related Art

In the semiconductor process, in order to form the device layout pattern on the substrate, the corresponding pattern may be designed in the computer system, the OPC process may be performed to generate the OPC pattern, and then the OPC pattern may be transferred to the photomask to form the photomask pattern. After that, the lithography step and the etching step are performed to transfer the photomask pattern to the material layer.

For most device layout patterns, when the pattern in the edge portion of the central region adjacent to the edge region and the pattern in the remaining portions of the central region have the same profile, different OPC patterns need to be generated due to differences in the surrounding environments However, during the OPC process, the pattern in the edge portion may be identified as two types at the same time due to the surrounding environment, such as being located in the edge portion and located in the remaining portions. As a result, the pattern is repeatedly identified and the correct final OPC pattern cannot be generated.

### SUMMARY

The present invention provides a method for generating an OPC pattern, which may prevent the pattern located in the edge portion of the central region adjacent to the edge region from being repeatedly identified.

The method for generating an OPC pattern of the present invention includes the following steps. A layout pattern including at least one first unit pattern in an edge region and a plurality of second unit patterns in a central region adjacent to the edge region is provided. A first OPC sub-pattern corresponding to the at least one first unit pattern and the second unit patterns in an edge portion of the central region adjacent the edge region is built. A second OPC sub-pattern corresponding to the second unit pattern is built. A mark covering the edge region and the edge portion is formed. The edge region is identified, and a first OPC pattern is obtained according to the first OPC sub-pattern. The central region except the edge portion is identified according to the mark, and a second OPC pattern is obtained according to the second OPC sub-pattern. An OPC pattern of the layout pattern is obtained by combining the first OPC pattern and the second OPC pattern.

The method for generating an OPC pattern of the present invention includes the following steps. A layout pattern including at least one first unit pattern in an edge region and a plurality of second unit patterns in a central region adjacent to the edge region is provided. A first OPC sub-pattern corresponding to the at least one first unit pattern and the second unit patterns in an edge portion of the central region adjacent the edge region is built. A second OPC sub-pattern corresponding to the second unit pattern is built. A first mark covering the edge region and the edge portion is formed. A second mark covering the central region except the edge portion is formed. The at least one first unit pattern and the second unit patterns that overlap with the first mark in the edge region and the edge portion is identified, and a first OPC pattern is obtained according to the first OPC sub-pattern. The second unit patterns that overlap with the second mark and do not overlap with the first mark in the central region is identified, and a second OPC pattern is obtained according to the second OPC sub-pattern. An OPC pattern of the layout pattern is obtained by combining the first OPC pattern and the second OPC pattern.

The method for generating an OPC pattern of the present invention includes the following steps. A layout pattern including at least one first unit pattern in an edge region and a plurality of second unit patterns in a central region adjacent to the edge region is provided. A first OPC sub-pattern corresponding to the at least one first unit pattern and the second unit patterns in an edge portion of the central region adjacent the edge region is built. A second OPC sub-pattern corresponding to the second unit pattern is built. A first target pattern corresponding to the second unit pattern in the edge portion is obtained. A second target pattern corresponding to the second unit pattern in the central region except the edge portion is obtained. The edge region is identified according to the first target pattern and the first OPC sub-pattern, and a first OPC pattern is obtained according to the first OPC sub-pattern. The central region is identified according to the second target pattern and the second OPC sub-pattern, and a second OPC pattern is obtained according to the second OPC sub-pattern. An OPC pattern of the layout pattern is obtained by combining the first OPC pattern and the second OPC pattern.

In an embodiment for generating an OPC pattern of the present invention, the first target pattern and the second target pattern are obtained from a target pattern database.

In an embodiment for generating an OPC pattern of the present invention, from a top view of the layout pattern, the second unit patterns have the same profile.

In an embodiment for generating an OPC pattern of the present invention, from a top view of the layout pattern, a profile of the first unit pattern is different from a profile of the second unit pattern.

In an embodiment for generating an OPC pattern of the present invention, the layout pattern corresponds to a layout of a static random access memory (SRAM).

Based on the above, in the method for generating an OPC pattern of the present invention, for the OPC patterns generated form the unit patterns in the edge region and the central region of the layout pattern, through the Boolean operation, the pre-treatment to form a mark, or referring to the target pattern, the unit pattern in the edge portion of the central region may be prevented from being identified as two types, resulting in repeated identification, and therefore the correct final OPC pattern may be generated.

### BRIEF DESCRIPTION OF THE DRAWINGS

FIG. 1 is a flow chart of the method of generating the OPC pattern according to the first embodiment of the present invention.

FIGS. 2A to 2F are schematic diagrams of the method for generating the OPC pattern according to the first embodiment of the present invention.

FIG. 3 is a flow chart of the method for generating the OPC pattern according to the second embodiment of the present invention.

FIGS. 4A to 4D are schematic diagrams of the method for generating the OPC pattern according to the second embodiment of the present invention.

FIG. 5 is a flow chart of the method for generating the OPC pattern according to the third embodiment of the present invention.

FIGS. 6A to 6D are schematic diagrams of the method for generating the OPC pattern according to the third embodiment of the present invention.

### DESCRIPTION OF THE EMBODIMENTS

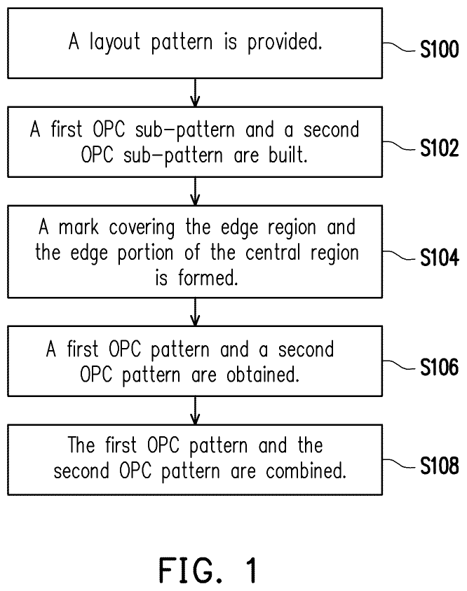

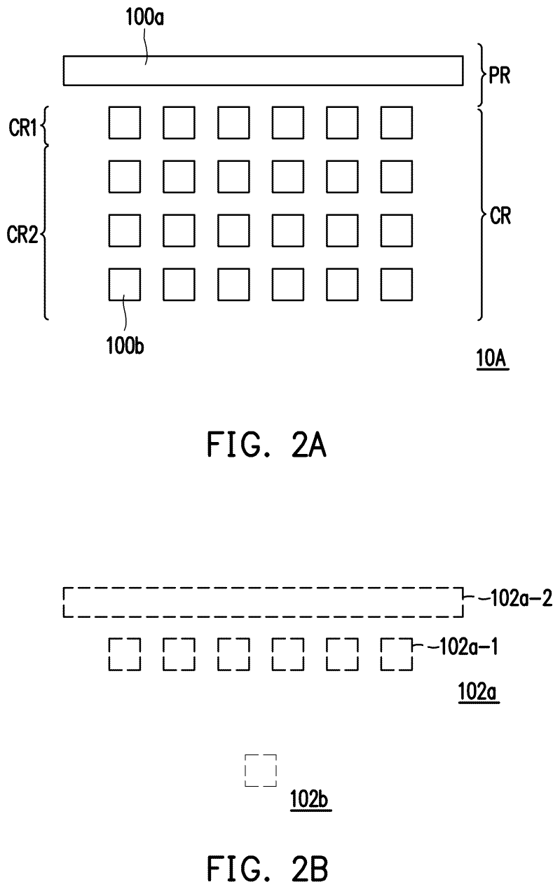

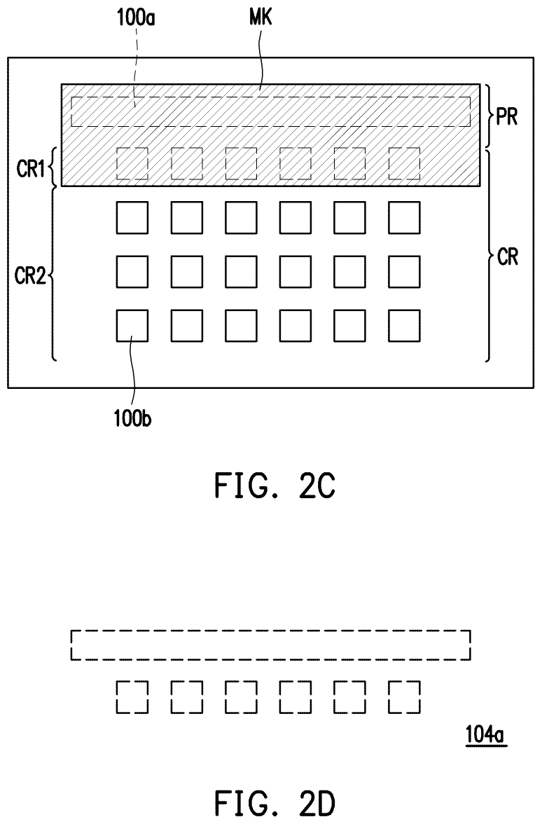

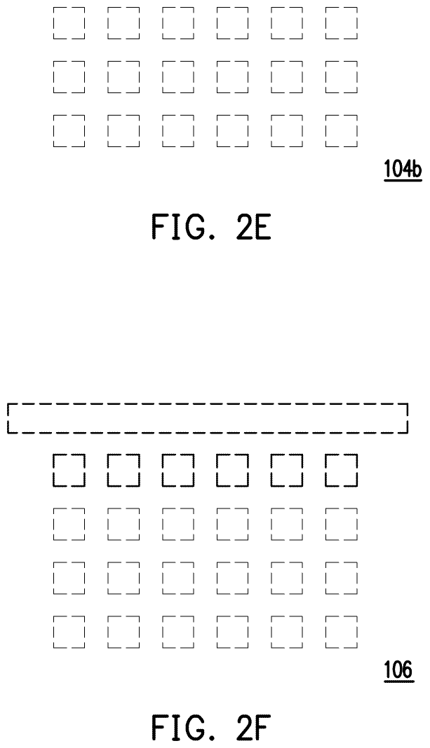

FIG. 1 is a flow chart of the method of generating the OPC pattern according to the first embodiment of the present invention. FIGS. 2A to 2F are schematic diagrams of the method for generating the OPC pattern according to the first embodiment of the present invention.

In the present embodiment, a layout of a static random access memory (SRAM) is used as an example to illustrate the method for generating the OPC pattern, but the present invention is not limited thereto. Those skilled in the art may apply the method to the layout of various other semiconductor apparatuses.

Referring to FIGS. 1 and 2A, in the step S100, a layout pattern 10A is provided. In the present embodiment, the layout pattern 10A corresponds to the layout of the SRAM. In detail, the layout pattern 10A may include an edge region PR and a central region CR adjacent to each other. A first unit pattern 100a is located in the edge region PR, and a plurality of second unit patterns 100b is located in the central region CR in the form of an array. In FIG. 2A, the number and configuration of the first unit pattern 100a and the second unit patterns 100b are only exemplary. From the top view of the layout pattern 10A, the profile of the first unit pattern 100a is different from the profile of the second unit pattern 100b, and these second unit patterns 100b have the same profile. In the case where the layout pattern 10A corresponds to the layout of the SRAM, the first unit pattern 100a may correspond to the gate pattern in the peripheral region, and the second unit pattern 100b may correspond to the memory cell pattern in the memory device region.

In addition, the central region CR includes an edge portion CR1 adjacent to the edge region PR and a remaining portion CR2. In the present embodiment, one row of the second unit patterns 100b is located in edge portion CR1. In the edge portion CR1, one side of the row of second unit patterns 100b is adjacent to the first unit pattern 100a in the edge region PR, and the other side of the row of the second unit patterns 100b is adjacent to other second unit patterns 100b. In the remaining portion CR2, each of the second unit patterns 100b is surrounded by other second unit patterns 100b. That is, the surrounding environment of the second unit pattern 100b in edge portion CR1 is different from the surrounding environment of the second unit pattern 100b in the remaining portion CR2, so when the OPC pattern is generated, the OPC pattern corresponding to the second unit pattern 100b in the edge portion CR1 must be different from the OPC pattern corresponding to the second unit pattern 100b in the remaining portion CR2.

Referring to FIGS. 1 and 2B, in the step S102, an OPC process is performed for the layout pattern 10A to build a first OPC sub-pattern 102a corresponding to the first unit pattern 100a and the second unit patterns 100b in the edge portion CR1, and build a second OPC sub-pattern 102b corresponding to one second unit pattern 100b. The first OPC sub-pattern 102a includes a first portion 102a-1 corresponding to the second unit pattern 100b in the edge portion CR1 and a second portion 102a-2 corresponding to the first unit pattern 100a in the edge region PR.

As described above, since the surrounding environment of the second unit pattern 100b in the edge portion CR1 is different from the surrounding environment of the second unit pattern 100b in the remaining portion CR2, even though these second unit patterns 100b have the same profile, the first portion 102a-1 of the first OPC sub-pattern 102a is different from the second OPC sub-pattern 102b.

Referring to FIGS. 1 and 2C, in the step S104, a mark MK covering the edge region PR and the edge portion CR1 of the central region CR is formed. The mark MK covers the first unit pattern 100a and the second unit patterns 100b in the edge portion CR1. In other words, after forming the mark MK, only the second unit patterns 100b with the same surrounding environment are exposed.

Referring to FIGS. 1, 2D and 2E, in the step S106, the edge region PR may be identified through the mark MK, and a first OPC pattern 104a corresponding to the edge region PR and the edge portion CR1 is obtained according to the first OPC sub-pattern 102a, as shown in FIG. 2D. In addition, the central region CR except the edge portion CR1, that is, the remaining portion CR2, is identified through the mark MK, and a second OPC pattern 104b corresponding to the remaining portion CR2 is obtained according to the second OPC sub-pattern 102b, as shown in FIG. 2E.

In detail, after identification, the position of the edge region PR is determined, and the first OPC sub-pattern 102a is used as the first OPC pattern 104a generated corresponding to the first unit pattern 100a in the edge region PR and the second unit patterns 100b in the edge portion CR1. In addition, after identification, the position of the remaining portion CR2 is determined, and the second OPC sub-pattern 102b is applied to each second unit pattern 100b in the remaining portion CR2 to generate the second OPC pattern 104b corresponding to second unit patterns 100b in the remaining portion CR2.

Referring to FIGS. 1 and 2F, in the step 108, the first OPC pattern 104a and the second OPC pattern 104b are combined to obtain a final OPC pattern 106 corresponding to the layout pattern 10A.

In the present embodiment, through the mark MK, the OPC patterns are generated respectively for the second unit pattern 100b in the edge portion CR1 and the second unit pattern 100b in the remaining portion CR2. As a result, the situation where the second unit pattern 100b in the edge portion CR1 is identified as two types, resulting in repeated identification, may be prevented, so that a correct final OPC pattern may be generated. In other words, in the present embodiment, a method similar to the Boolean operation is used. After excluding the edge region PR and the edge portion CR1 from the layout pattern 10A, the OPC pattern is generated for the remaining portion CR2, and then combined with the OPC pattern generated for the edge region PR and the edge portion CR1 to form the final OPC pattern.

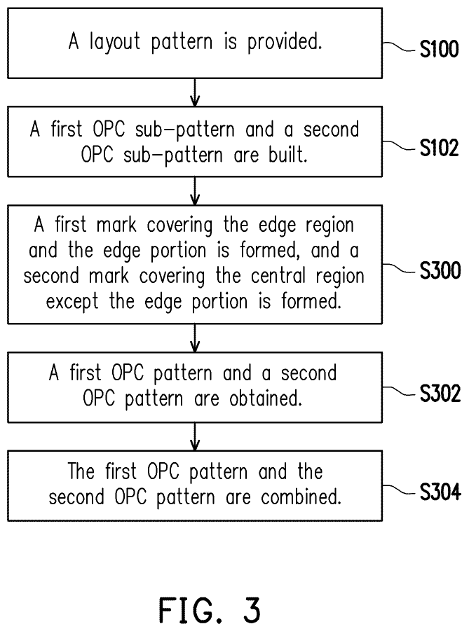

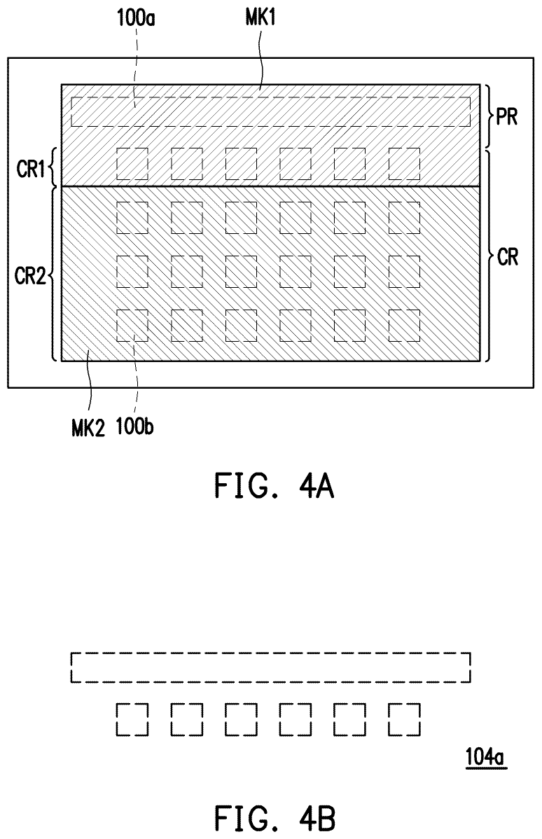

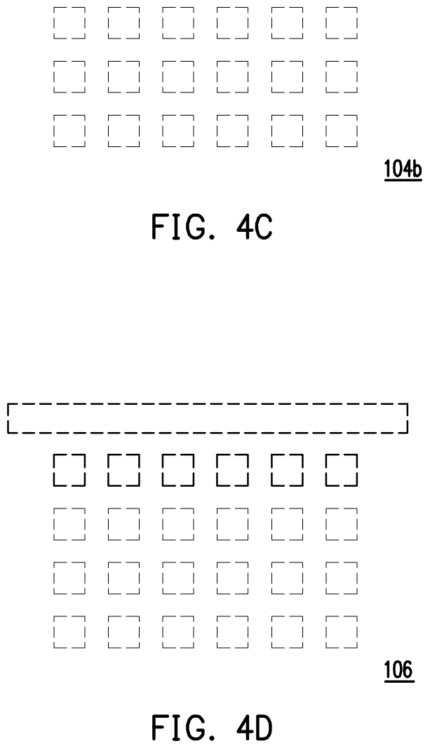

FIG. 3 is a flow chart of the method for generating the OPC pattern according to the second embodiment of the present invention. FIGS. 4A to 4D are schematic diagrams of the method for generating the OPC pattern according to the second embodiment of the present invention. In the present embodiment, a device which is the same as that in the first embodiment will be represented by the same reference symbol, and will not be described again.

Referring to FIGS. 3 and 4A, after the step S100 and the step 102 described in FIG. 1 are performed, in the step S300, a first mark MK1 covering the edge region PR and the edge portion CR1 is formed, and a second mark MK2 covering the remaining portion CR2 is formed.

Referring to FIGS. 3, 4B and 4C, in the step S302, the first unit pattern 100a and the second unit patterns 100b that overlap with the first mark MK1 in the edge region PR and the edge portion CR1 are identified, and the first OPC pattern 104a corresponding to the edge region PR and the edge portion CR1 is obtained according to the first OPC sub-pattern 102a, as shown in FIG. 4B. In addition, the second unit patterns 100b in the central region CR that overlap with the second mark MK2 and do not overlap with the first mark MK1, and the second OPC pattern 104b corresponding to the remaining portion CR2 is obtained according to the second OPC sub-pattern 102b, as shown in FIG. 4C.

After identification, it is determined that the first unit pattern 100a and the second unit patterns 100b in the edge region PR and the edge portion CR1 overlap with the first mark MK1. Therefore, the first OPC sub-pattern 102a may be used as the first OPC pattern 104a generated corresponding to the first unit pattern 100a in the edge region PR and the second unit patterns 100b in the edge portion CR1. In addition, after identification, the second unit patterns 100b in the central region CR that overlap with the second mark MK2 and do not overlap with the first mark MK1 may be determined to be not located in the edge portion CR1, so the second OPC sub-pattern 102b is applied to these second unit patterns 100b to generate the second OPC pattern 104b corresponding to second unit patterns 100b in the remaining portion CR2.

Referring to FIGS. 3 and 4D, in the step S304, the first OPC pattern 104a and the second OPC pattern 104b are combined to obtain the final OPC pattern 106 corresponding to the layout pattern 10A.

In the present embodiment, the first mark MK1 is used to cover the edge region PR and the edge portion CR1, and the second mark MK2 is used to cover the remaining portion CR2. In addition, the OPC patterns are generated respectively for the second unit patterns 100b that overlap with the first mark MK1 and the second unit patterns 100b that overlap with the second mark MK2. As a result, the situation where the second unit pattern 100b in the edge portion CR1 is identified as two types, resulting in repeated identification, may be prevented, so that a correct final OPC pattern may be generated.

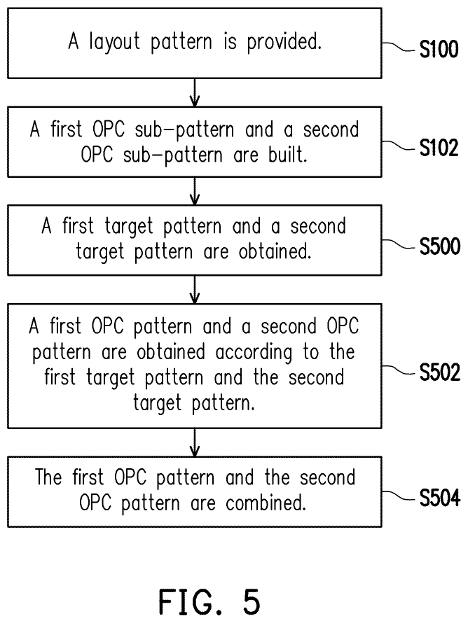

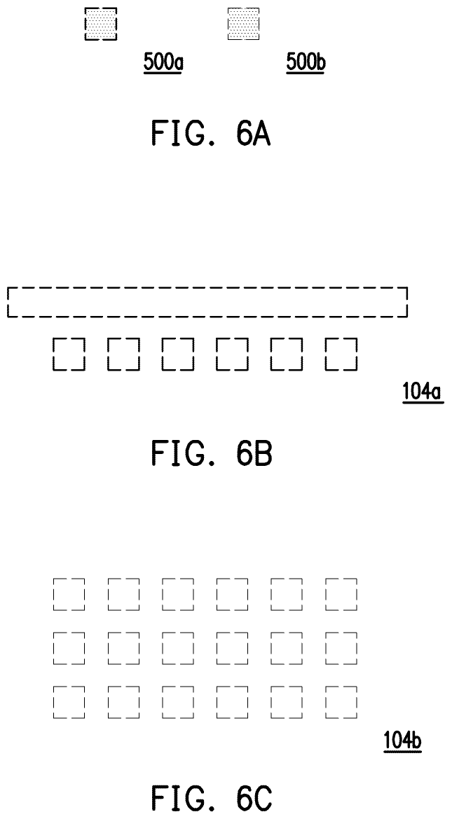

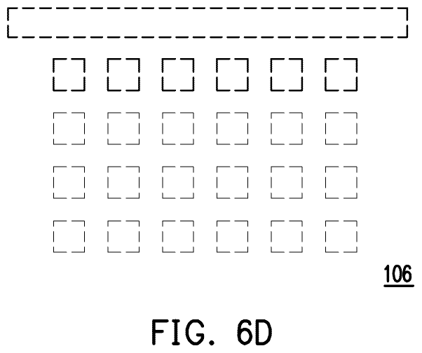

FIG. 5 is a flow chart of the method for generating the OPC pattern according to the third embodiment of the present invention. FIGS. 6A to 6D are schematic diagrams of the method for generating the OPC pattern according to the third embodiment of the present invention. In the present embodiment, a device which is the same as that in the first embodiment will be represented by the same reference symbol, and will not be described again.

Referring to FIGS. 5 and 6A, after the step S100 and the step 102 described in FIG. 1 are performed, in the step S500, a first target pattern 500a is obtained corresponding to the second unit patterns 100b in edge portion CR1, and a second target pattern 500b is obtained corresponding to the second unit pattern 100b in the remaining portion CR2. For example, the OPC patterns generated respectively for the second unit pattern 100b in the edge portion CR1 and the second unit pattern 100b in the remaining portion may be obtained from a target pattern database as reference patterns.

Referring to FIGS. 5, 6B and 6C, in the step S502, the edge region PR is identified according to the first target pattern 500a and the first OPC sub-pattern 102a, and the first OPC pattern 104a corresponding to the edge region PR and the edge portion CR1 is obtained according to the first OPC sub-pattern 102a. In addition, the central region CR is identified according to the second target pattern 500b and the second OPC sub-pattern 102b, and the second OPC pattern 104b corresponding to the remaining portion CR2 is obtained according to the second OPC sub-pattern 102b.

In detail, in step S502, the first portion 102a-1 of the first OPC sub-pattern 102a is compared with the first target pattern 500a, and when the two are the same or similar, the first OPC sub-pattern 102a is used as the first OPC pattern 104a generated corresponding to the first unit pattern 100a in the edge region PR and the second unit patterns 100b in edge portion CR1. In addition, the second OPC sub-pattern 102b is compared with the second target pattern 500b, and when the two are the same or similar, the second OPC sub-pattern 102b is applied to these second unit pattern 100b to generate the second OPC pattern 104b corresponding to the second unit patterns 100b in the remaining portion CR2.

Referring to FIGS. 5 and 6D, in the step S504, the first OPC pattern 104a and the second OPC pattern 104b are combined to obtain a final OPC pattern 106 corresponding to the layout pattern 10A.

In the present embodiment, the OPC pattern of the second unit pattern 100b in the edge portion CR1 and the OPC pattern of the second unit pattern 100b in the remaining portion CR2 are compared with the respective target pattern in the target pattern database, and when the same or similar to the target pattern, the second unit patterns 100b in the edge portion CR1 may be correctly distinguished from the second unit patterns 100b in the remaining portion CR2. As a result, the situation where the second unit pattern 100b in the edge portion CR1 is identified as two types, resulting in repeated identification, may be prevented, so that a correct final OPC pattern may be generated.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for generating an optical proximity correction (OPC) pattern, comprising:
providing a layout pattern comprising at least one first unit pattern in an edge region and a plurality of second unit patterns in a central region adjacent to the edge region;
building a first OPC sub-pattern corresponding to the at least one first unit pattern and the second unit patterns in an edge portion of the central region adjacent the edge region;
building a second OPC sub-pattern corresponding to the second unit pattern;
forming a mark covering the edge region and the edge portion;
identifying the edge region and obtaining a first OPC pattern according to the first OPC sub-pattern;
identifying the central region except the edge portion according to the mark and obtaining a second OPC pattern according to the second OPC sub-pattern; and
obtaining an OPC pattern of the layout pattern by combining the first OPC pattern and the second OPC pattern.

2. The method of claim 1, wherein from a top view of the layout pattern, the second unit patterns have the same profile.

3. The method of claim 1, wherein from a top view of the layout pattern, a profile of the first unit pattern is different from a profile of the second unit pattern.

4. The method of claim 1, wherein the layout pattern corresponds to a layout of a static random access memory (SRAM).

5. A method for generating an OPC pattern, comprising:
providing a layout pattern comprising at least one first unit pattern in an edge region and a plurality of second unit patterns in a central region adjacent to the edge region;
building a first OPC sub-pattern corresponding to the at least one first unit pattern and the second unit patterns in an edge portion of the central region adjacent the edge region;
building a second OPC sub-pattern corresponding to the second unit pattern;
forming a first mark covering the edge region and the edge portion;
forming a second mark covering the central region except the edge portion;
identifying the at least one first unit pattern and the second unit patterns that overlap with the first mark in the edge region and the edge portion and obtaining a first OPC pattern according to the first OPC sub-pattern;
identifying the second unit patterns that overlap with the second mark and do not overlap with the first mark in the central region and obtaining a second OPC pattern according to the second OPC sub-pattern; and
obtaining an OPC pattern of the layout pattern by combining the first OPC pattern and the second OPC pattern.

6. The method of claim 5, wherein from a top view of the layout pattern, the second unit patterns have the same profile.

7. The method of claim 5, wherein from a top view of the layout pattern, a profile of the first unit pattern is different from a profile of the second unit pattern.

8. The method of claim 5, wherein the layout pattern corresponds to a layout of an SRAM.

9. A method for generating an OPC pattern, comprising:
providing a layout pattern comprising at least one first unit pattern in an edge region and a plurality of second unit patterns in a central region adjacent to the edge region;
building a first OPC sub-pattern corresponding to the at least one first unit pattern and the second unit patterns in an edge portion of the central region adjacent the edge region;
building a second OPC sub-pattern corresponding to the second unit pattern;
obtaining a first target pattern corresponding to the second unit pattern in the edge portion;
obtaining a second target pattern corresponding to the second unit pattern in the central region except the edge portion;
identifying the edge region according to the first target pattern and the first OPC sub-pattern and obtaining a first OPC pattern according to the first OPC sub-pattern;
identifying the central region according to the second target pattern and the second OPC sub-pattern and obtaining a second OPC pattern according to the second OPC sub-pattern; and
obtaining an OPC pattern of the layout pattern by combining the first OPC pattern and the second OPC pattern.

10. The method of claim 9, wherein from a top view of the layout pattern, the second unit patterns have the same profile.

11. The method of claim 9, wherein from a top view of the layout pattern, a profile of the first unit pattern is different from a profile of the second unit pattern.

12. The method of claim 9, wherein the layout pattern corresponds to a layout of an SRAM.

13. The method of claim 9, wherein the first target pattern and the second target pattern are obtained from a target pattern database.
